(19) United States
(12) Patent Application Publication
(10) Pub. No.: US 2025/0017083 A1
(43) Pub. Date: Jan. 9, 2025

(54) DISPLAY DEVICE AND METHOD OF MANUFACTURING THE SAME

(71) Applicant: Samsung Display Co., Ltd., Yongin-si (KR)

(72) Inventors: YEONJU SEO, Yongin-si (KR); NAMJIN KIM, Yongin-si (KR); DEOK-YOUNG CHOI, Yongin-si (KR); MIKYUNG KIM, Yongin-si (KR)

(21) Appl. No.: 18/651,262

(22) Filed: Apr. 30, 2024

(30) Foreign Application Priority Data
Jul. 7, 2023 (KR) 10-2023-0088152

(51) Int. Cl. H10K 59/80; H10K 59/12; H10K 59/131; H10K 59/40

(52) U.S. Cl. CPC H10K 59/8731; H10K 59/1201; H10K 59/131; H10K 59/40

(57) ABSTRACT

A display device includes: a base layer having a display area and a non-display area adjacent to the display area; a display element layer including a plurality of light emitting elements overlapping the display area; an encapsulation layer on the display element layer; a first dam in the non-display area; and a second dam in the non-display area and spaced apart from the first dam in a direction away from the display area from a boundary between the display area and the non-display area. An inorganic layer area is defined between the first dam and the second dam, and a groove is defined in the inorganic layer area.

### CROSS-REFERENCE TO RELATED APPLICATION

This application claims priority to and the benefit of Korean Patent Application No. 10-2023-0088152, filed on Jul. 7, 2023, the content of which is hereby incorporated by reference in its entirety.

### BACKGROUND

### 1. Field

Aspects of embodiments of the present disclosure relate to a display device and a method of manufacturing the display device.

### 2. Description of the Related Art

Display devices that provide images to a user, for example, a television set, a monitor, a smart phone, and a tablet computer, generally include a display panel to display the images. Various suitable kinds of display panels, such as a liquid crystal display panel, an organic light emitting display panel, an electrowetting display panel, and an electrophoretic display panel, are being developed. In response to recent market demands, research is being conducted to resolve or prevent defects in the display panel that are caused by foreign substances infiltrating into the display panel.

### SUMMARY

Embodiments of the present disclosure provide a display device in which defects in a display panel caused by foreign substances are avoided or mitigated.

Embodiments of the present disclosure provide a method of manufacturing the display device in which defects in the display panel caused by foreign substances are avoided or mitigated.

According to an embodiment of the present disclosure, a display device includes: a base layer having a display area and a non-display area adjacent to the display area; a display element layer including a plurality of light emitting elements overlapping the display area; an encapsulation layer on the display element layer; a first dam in the non-display area; and a second dam in the non-display area and spaced apart from the first dam in a direction away from the display area from a boundary between the display area and the non-display area. An inorganic layer area is defined between the first dam and the second dam, and a groove is defined in the inorganic layer area.

The encapsulation layer may include a first inorganic layer, an organic layer, and a second inorganic layer, which are sequentially arranged on the display element layer, and the second inorganic layer may be in contact with the first inorganic layer in the inorganic layer area.

The display device may further include a sensor layer including a first sensing insulating layer, a first conductive layer, a second sensing insulating layer, a second conductive layer, and a third sensing insulating layer, which are sequentially arranged on the encapsulation layer, and the second sensing insulating layer may be in contact with the first sensing insulating layer and the third sensing insulating layer in the inorganic layer area.

The groove may be defined in the first inorganic layer, the second inorganic layer, the first sensing insulating layer, and the second sensing insulating layer.

The groove may be defined closer to the second dam than to the first dam when viewed in a plane.

The third sensing insulating layer may be on the second sensing insulating layer and may cover the groove.

A contact hole at where the first conductive layer and the second conductive layer are connected to each other may extend through the second sensing insulating layer, and the groove may be formed through a same process as the contact hole.

The groove may be spaced apart from the first dam by 25 micrometers or more.

The groove may have a width equal to or smaller than 10 micrometers in a first direction.

According to another embodiment of the present disclosure, a display device includes: a base layer having a display area and a non-display area adjacent to the display area; a display element layer including a plurality of light emitting elements overlapping the display area; an encapsulation layer including a first inorganic layer, an organic layer, and a second inorganic layer, which are sequentially arranged on the display element layer; and a sensor layer including a first sensing insulating layer, a first conductive layer, a second sensing insulating layer, a second conductive layer, and a third sensing insulating layer, which are sequentially arranged on the encapsulation layer. A groove is defined in the first inorganic layer, the second inorganic layer, the first sensing insulating layer, and the second sensing insulating layer, and the groove overlaps the non-display area.

The display device may further include: a first dam in the non-display area; and a second dam in the non-display area and spaced apart from the first dam in a direction away from the display area from a boundary between the display area and the non-display area. An inorganic layer area may be defined between the first dam and the second dam, and the groove maybe defined in the inorganic layer area.

The first inorganic layer, the second inorganic layer, the first sensing insulating layer, the second sensing insulating layer, and the third sensing insulating layer may be sequentially stacked in the inorganic layer area.

The groove may be spaced apart from the first dam by 25 micrometers or more.

A contact hole at where the first conductive layer and the second conductive layer are connected to each other may be defined through the second sensing insulating layer, and the groove may be formed through a same process as the contact hole.

The third sensing insulating layer may be on the second sensing insulating layer and covers the groove.

The groove may have a width equal to or smaller than 10 micrometers in a first direction.

According to another embodiment of the present disclosure, a method of manufacturing a display device includes: preparing a display panel including a base layer in which a display area and a non-display area adjacent to the display area are defined, a circuit layer on the base layer, a display element layer on the circuit layer, and an encapsulation layer including a first inorganic layer, an organic layer, and a second inorganic layer, which are sequentially stacked on the display element layer; sequentially stacking a first sensing insulating layer, a first conductive layer, and a second sensing insulating layer on the display panel; forming a hole through the first inorganic layer, the second inorganic layer, the first sensing insulating layer, and the second sensing insulating layer, which overlap the non-display area; and sequentially stacking a second conductive layer and a third sensing insulating layer on the second sensing insulating layer.

The forming of the hole may include forming a contact hole at where the first conductive layer and the second conductive layer are connected to each other.

The display panel may further include a first dam in the non-display area and a second dam spaced apart from the first dam in a direction away from the display area from a boundary between the display area and the non-display area. The forming of the hole may include etching the first inorganic layer, the second inorganic layer, the first sensing insulating layer, and the second sensing insulating layer in an area spaced apart from the first dam by 25 micrometers or more.

The forming of the hole may include etching the first inorganic layer, the second inorganic layer, the first sensing insulating layer, and the second sensing insulating layer such that the hole has a width equal to or smaller than 10 micrometers.

Because a groove is formed in an inorganic layer area, a foreign substance from the outside is discharged upwardly through the groove. Therefore, the foreign substance is prevented from moving along (or into) the display area, and defects in the display panel are reduced or avoided. In addition, because the groove is formed by using the same mask as a mask used to form a contact hole for the input sensor, the manufacturing process of the display panel is simplified.

### BRIEF DESCRIPTION OF THE DRAWINGS

The above and other aspects and features of the present disclosure will become readily apparent by reference to the following detailed description when considered in conjunction with the accompanying drawings, in which:

FIG. 1 is a perspective view of a display device according to an embodiment of the present disclosure;

FIG. 2 is a cross-sectional view of a display device according to an embodiment of the present disclosure;

FIG. 3 is a cross-sectional view of a display panel according to an embodiment of the present disclosure;

FIG. 4 is a cross-sectional view of a display panel and an input sensor according to an embodiment of the present disclosure;

FIG. 5 is a plan view of a display panel according to an embodiment of the present disclosure;

FIG. 6 is a plan view of an input sensor according to an embodiment of the present disclosure;

FIG. 7 is a cross-sectional view of the display panel and the input sensor taken along the line I-I′ in FIG. 5 according to an embodiment of the present disclosure;

FIGS. 8 to 10 are enlarged views of the area AA′ of FIG. 7 according to various embodiments; and

FIGS. 11A to 11D are cross-sectional views illustrating steps of a method of manufacturing a display device according to an embodiment of the present disclosure.

### DETAILED DESCRIPTION

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the present disclosure will be described with reference to accompanying drawings.

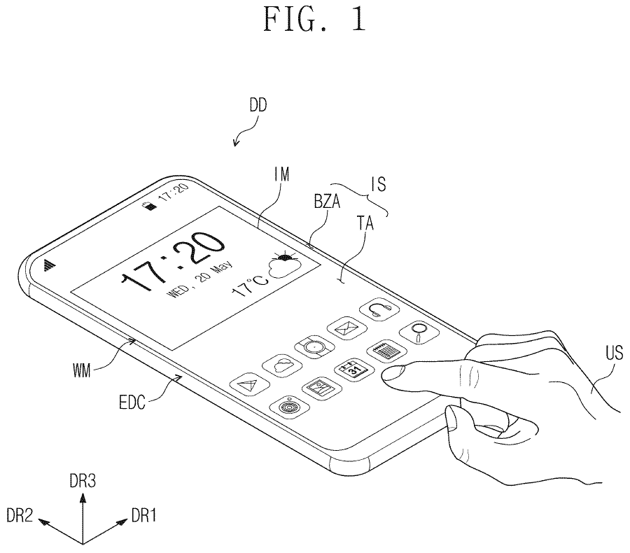

FIG. 1 is a perspective view of a display device DD according to an embodiment of the present disclosure.

The display device DD may be activated in response to electrical signals and may display an image IM. As an example, the display device DD may be applied to a large-sized electronic item, such as a television set, an outdoor billboard, etc., or to small and medium-sized electronic items, such as a monitor, a mobile phone, a tablet computer, a navigation unit, a game unit, etc. However, these are merely examples, and the display device DD may be applied to other electronic devices as long as they do not depart from the concept of the present disclosure. In the present embodiment, a mobile phone is shown as an example of the display device DD.

The display device DD, according to embodiments of the present disclosure, may be flexible. The term “flexible” as used herein refers to a property of being able to be bent, including the ability to be completely bent to the ability to be bent at the scale of a few nanometers. For example, the display device DD may be a curved display device or a foldable display device. According to other embodiments, the display device DD may be rigid.

Referring to FIG. 1, the display device DD may have a rectangular shape defined by short sides extending in a first direction DR1 and long sides extending in a second direction DR2 crossing the first direction DR1. However, the shape of the display device DD is not limited to the rectangular shape, and the display device DD may have a variety of shapes, such as a circular shape and a polygonal shape when viewed in a plane.

The display device DD may display the image IM on a display surface IS in a third direction DR3 substantially perpendicular to a plane defined by the first direction DR1 and the second direction DR2. The image IM emitted from the display device DD may include a still image as well as a video. FIG. 1 shows a clock widget and application icons as a representative example of the image IM, but the present disclosure is not limited thereto.

The display surface IS through which the image IM is displayed may correspond to a front surface of the display device DD and a front surface of a window WM. Hereinafter, the front surface of the window WM will be designated by the same reference numeral as that of the display surface IS. FIG. 1 shows a flat display surface IS, however, according to various embodiments, the display surface IS of the display device DD may have a curved shape bent from at least one side of the plane.

Front (or upper) and rear (or lower) surfaces of each member of the display device DD may be opposite to each other in the third direction DR3, and a normal direction of each of the front and rear surfaces may be substantially parallel to the third direction DR3. A separation distance between the front and rear surfaces of each member (or each unit) in the third direction DR3 may correspond to a thickness of the member (or the unit) in the third direction DR3. In the present disclosure, the expression “when viewed in a plane” “or viewed on a plane” means a state of being viewed in the third direction DR3. Directions indicated by the first, second, and third directions DR1, DR2, and DR3 are relative to each other, and thus, the directions indicated by the first, second, and third directions DR1, DR2, and DR3 may be changed to other directions.

The display device DD may sense (or detect) an external input applied thereto from the outside. The external input may include a variety of external inputs provided from the outside of the display device DD. For example, the external inputs may include force, pressure, temperature, light, etc. The external inputs may include an external input (e.g., a hovering input) applied when a touch input, e.g., a hand of a user or a pen, is in close proximity to or approaches close to the display device DD at a reference distance (e.g., a predetermined distance).

In the present embodiment, a touch input by the user US applied to the front surface of the display device DD is shown as a representative example of the external input. However, this is merely an example, and the external input may include all inputs causing a change of a capacitance and is not particularly limited. In addition, the area of the display device DD in which the external input is sensed should not be limited to the front surface of the display device DD. The display device DD may sense the input by the user US applied to a side or rear surface of the display device DD depending on its design.

Referring to FIG. 1, the display device DD may include the window WM and a case EDC. The window WM and the case EDC may be coupled to each other to form an outer shape (or outer appearance) of the display device DD and may provide an inner space in which components of the display device DD are accommodated. As an example, the components of the display device DD, such as a display panel, an input sensor, a protective member, an electronic module, etc., may be accommodated between the window WM and the case EDC.

The front surface IS (or the display surface) of the window WM may have a transmission area TA and a bezel area BZA. The transmission area TA may be an optically transparent area. Accordingly, the image IM emitted from the display device DD may be displayed through (e.g., may pass through or may be emitted through) the transmission area TA, and the user US may view the image IM. In the present embodiment, the transmission area TA has a quadrangular shape with rounded vertices, however, this is merely an example. The transmission area TA may have a variety of shapes and is not particularly limited.

The bezel area BZA may be defined adjacent to the transmission area TA. As an example, the bezel area BZA may be disposed outside the transmission area TA and may surround (e.g., may surround, in a plan view, or may extend around a periphery of) the transmission area TA. Accordingly, the transmission area TA may have a shape defined by the bezel area BZA. However, this is merely an example, and the bezel area BZA may be disposed adjacent to only one side of the transmission area TA or may be omitted. In addition, the bezel area BZA may be disposed at a side surface of the display device DD rather than the front surface of the display device DD.

The bezel area BZA may have a color (e.g., a predetermined color) and may block light. The bezel area BZA of the window WM may prevent components of the display device DD, which are disposed to overlap (e.g., which are arranged beneath) the bezel area BZA, from being viewed from the outside.

The case EDC may include a glass, plastic, or metal material having a relatively high rigidity. The case EDC may protect the components accommodated therein. To this end, the case EDC may absorb impacts applied thereto from the outside and may prevent a foreign substance and moisture from entering the components of the display device DD accommodated in the case EDC. The case EDC may be provided in a form obtained by coupling a plurality of accommodating members.

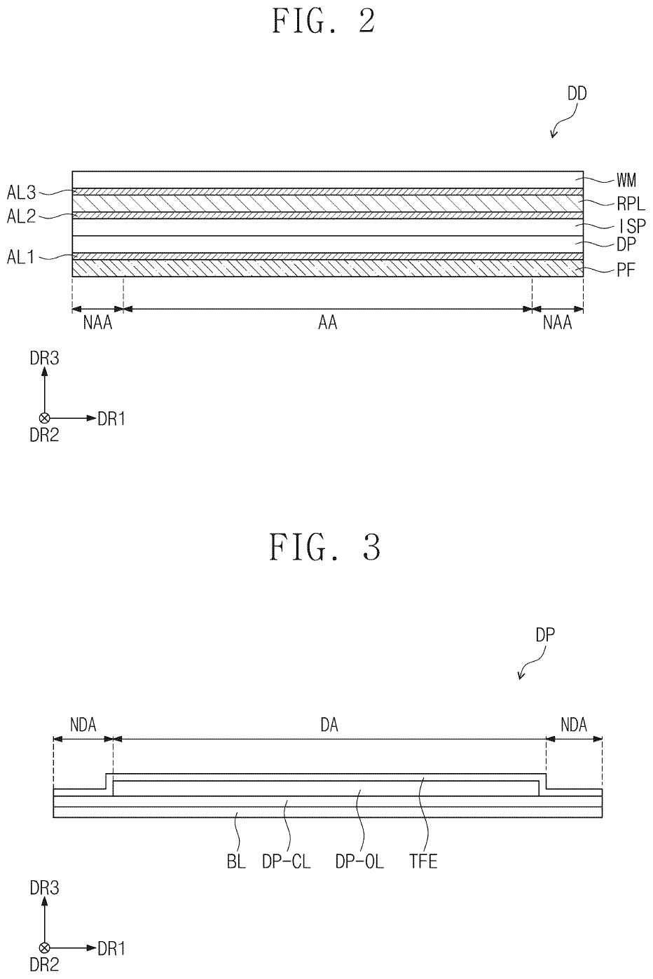

FIG. 2 is a cross-sectional view of the display device DD according to an embodiment of the present disclosure. FIG. 2 schematically shows a stacked structure of the components of the display device DD.

Referring to FIG. 2, the display device DD may include a display panel DP, an input sensor ISP, a protective member PF, an anti-reflective layer RPL, the window WM, and adhesive layers AL1, AL2, and AL3. The components of the display device DD disposed under the window WM may be disposed between the window WM and the case EDC and may be accommodated in the case EDC.

The display device DD may have an active area AA and a peripheral area NAA. The active area AA may be electrically activated. The display device DD may display an image through the active area AA and may sense the external input through the active area AA. The active area AA may correspond to the transmission area TA (see, e.g., FIG. 1).

The peripheral area NAA may be an area in which elements used to activate the active area AA are disposed. The peripheral area NAA may be defined adjacent to an outer side of the active area AA. As an example, the peripheral area NAA may surround (e.g., may surround, in a plan view, or may extend around a periphery of) the active area AA. The peripheral area NAA may correspond to the bezel area BZA (refer to FIG. 1).

In the following description, the expression “an area/portion corresponds to another area/portion” means that “an area/portion overlaps another area/portion”; however, the areas/portions are not limited to having the same size or the same shape unless expressly defined otherwise.

The display panel DP may display the image in response to the electrical signals. According to an embodiment, the display panel DP may be a light-emitting type display panel, however, it is not particularly limited. For instance, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot and/or a quantum rod. Hereinafter, the organic light emitting display panel will be described as a representative example of the display panel DP.

The input sensor ISP may be disposed on the display panel DP. The input sensor ISP may be disposed directly on the display panel DP without a separate adhesive member. That is, the input sensor ISP may be formed on a base surface provided by the display panel DP through successive processes after the display panel DP is formed, however, the present disclosure is limited thereto or thereby. According to an embodiment, the input sensor ISP may be attached to an upper surface of the display panel DP by an adhesive member after being manufactured through a separate process from the display panel DP.

The input sensor ISP may sense an external input applied thereto from the outside and may obtain coordinate information about the external input. The input sensor ISP may operate in various manners, such as a capacitive manner, a resistive manner, an infrared manner, or a pressure manner, and is not particularly limited.

The protective member PF may be disposed on a rear surface of the display panel DP. The protective member PF may include at least one of a protective film layer, an impact absorbing layer, and a support plate layer to protect the display panel DP from external impacts.

The protective film layer may include a flexible polymer material, such as polyethylene terephthalate, polyimide, or the like, and may protect the display panel DP. The impact absorbing layer may include a sponge, a foam, or a urethane resin and may absorb the external impacts applied to the display panel DP. The support plate layer may include a metal material having relatively high rigidity, such as stainless steel, aluminum, or alloys thereof, and may support the display panel DP under the display panel DP. Materials for the protective member PF are not particularly limited as long as the protective member PF may protect the display panel DP.

The anti-reflective layer RPL may be disposed on the input sensor ISP. The anti-reflective layer RPL may reduce a reflectance of external light incident thereto from above the display device DD.

According to an embodiment, the anti-reflective layer RPL may include a retarder and/or a polarizer. The retarder may include a λ/2 (e.g., a half-wave) retarder and/or a λ/4 (e.g., a quarter-wave) retarder. The polarizer may be a film type or liquid crystal coating type. The film type polarizer may include a stretching-type synthetic resin film, and the liquid crystal coating type polarizer may include liquid crystals aligned in an alignment (e.g., in a predetermined alignment). However, the retarder and the polarizer are not limited thereto or thereby, and the retarder and the polarizer may be implemented as one polarizing film.

According to an embodiment, the anti-reflective layer RPL may include color filters. The color filters may be arranged according to (or in consideration of) arrangements and emission colors of the pixels included in the display panel DP. The color filters may receive the external light and may filter the external light to the same color as the emission colors of the pixels. The anti-reflective layer RPL may further include a black matrix disposed adjacent to the color filters.

According to an embodiment, the anti-reflective layer RPL may include a destructive interference structure. For instance, the destructive interference structure may include a first reflection layer and a second reflection layer, which are disposed on different layers from each other. A first reflection light and a second reflection light, which are respectively reflected by the first reflection layer and the second reflection layer, may experience destructive interference, and thus, the anti-reflective layer RPL may reduce the reflectance of the external light.

The window WM may be disposed on the display panel DP. The window WM may have a shape corresponding to a shape of the display panel DP. The window WM may cover an entire external surface of the display panel DP and may protect the display panel DP from external impacts and scratches.

The window WM may include an optically transparent insulating material. As an example, the window WM may include a glass, sapphire, or polymer. The window WM may have a single-layer or multi-layer structure. The window WM may further include functional layers, such as an anti-fingerprint layer, a phase control layer, a hard coating layer, etc., disposed on an optically transparent substrate.

The adhesive layers AL1, AL2, and AL3 may include a first adhesive layer AL1, a second adhesive layer AL2, and a third adhesive layer AL3. The first adhesive layer AL1 may be disposed between the display panel DP and the protective member PF, and the display panel DP and the protective member PF may be coupled to each other by the first adhesive layer AL1. The second adhesive layer AL2 may be disposed between the anti-reflective layer RPL and the input sensor ISP, and the anti-reflective layer RPL and the input sensor ISP may be coupled to each other by the second adhesive layer AL2. The third adhesive layer AL3 may be disposed between the window WM and the anti-reflective layer RPL, and the window WM and the anti-reflective layer RPL may be coupled to each other by the third adhesive layer AL3. According to various embodiments, at least one of the first, second, and third adhesive layers AL1, AL2, and AL3 may be omitted.

Each of the first, second, and third adhesive layers AL1, AL2, and AL3 may include a transparent adhesive, such as an optically clear adhesive (OCA) film, an optically clear resin (OCR), or a pressure sensitive adhesive (PSA) film; however, the adhesive included in the first, second, and third adhesive layers AL1, AL2, and AL3 is not limited thereto or thereby.

The display device DD may further include an electronic module including a variety of functional modules to drive the display panel DP and a power supply module supplying a power required for an overall operation of the display device DD. As an example, the display device DD may include a camera module as a representative example of the electronic module.

FIG. 3 is a cross-sectional view of the display panel DP according to an embodiment of the present disclosure.

Referring to FIG. 3, the display panel DP may include a base layer BL, a circuit layer DP-CL, a display element layer DP-OL, and an encapsulation layer TFE.

The base layer BL may provide a base surface on which the circuit layer DP-CL is disposed. The base layer BL may be a rigid substrate; however, it is not limited thereto or thereby. According to another embodiment, the base layer BL may be a flexible substrate.

The base layer BL may have a display area DA and a non-display area NDA. The display area DA of the display panel DP may be activated in response to electrical signals, and the image may be displayed through (or on) the display area DA. According to an embodiment, the display area DA of the display panel DP may correspond to the transmission area TA (see, e.g., FIG. 1) of the window WM (see, e.g., FIG. 1) and the active area AA (see, e.g., FIG. 2) of the display device DD (see, e.g., FIG. 2).

According to an embodiment, a driving circuit or a driving line to drive the elements disposed in the display area DA, various signal lines to provide electrical signals to the elements, and pads may be disposed in the non-display area NDA. The non-display area NDA of the display panel DP may correspond to the bezel area BZA (see, e.g., FIG. 1) of the window WM (see, e.g., FIG. 1) and the non-display area NDA (see, e.g., FIG. 2) of the display device DD. Components of the display panel DP, which are disposed in the non-display area NDA, may be prevented from being viewed from the outside by the bezel area BZA.

The circuit layer DP-CL may be disposed on the base layer BL. The circuit layer DP-CL may include at least one insulating layer, driving elements, signal lines, and signal pads.

The display element layer DP-OL may be disposed on the circuit layer DP-CL. The display element layer DP-OL may include light emitting elements disposed to overlap the display area DA. The light emitting elements in the display element layer DP-OL may be electrically connected to the driving elements in the circuit layer DP-CL and may provide a source light via the display area DA in response to a signal from the driving elements.

The encapsulation layer TFE may be disposed on the display element layer DP-OL and may encapsulate the light emitting elements. The encapsulation layer TFE may include a plurality of insulating layers. The insulating layers of the encapsulation layer TFE may be disposed to improve an optical efficiency of the light emitting elements or to protect the light emitting elements.

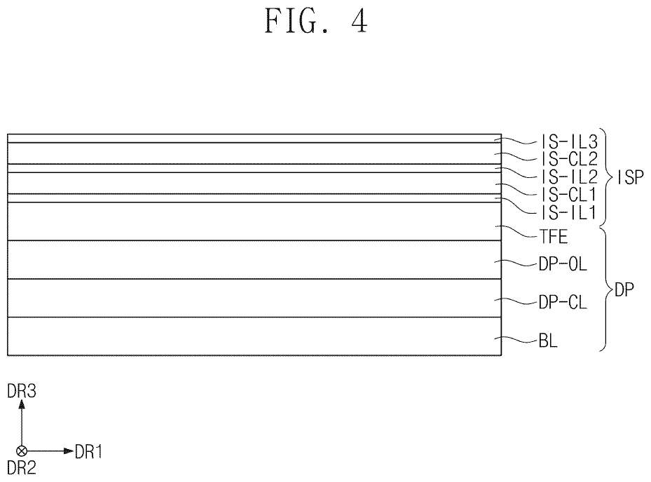

FIG. 4 is a cross-sectional view of the display panel DP and the input sensor ISP according to an embodiment of the present disclosure.

Referring to FIG. 4, the input sensor ISP may include a first sensing insulating layer IS-IL1, a first conductive layer IS-CL1, a second sensing insulating layer IS-IL2, a second conductive layer IS-CL2, and a third sensing insulating layer IS-IL3. The first sensing insulating layer IS-IL1 of the input sensor ISP may be disposed directly on the encapsulation layer TFE. According to another embodiment, the first sensing insulating layer IS-IL1 of the input sensor ISP may be omitted.

Each of the first conductive layer IS-CL1 and the second conductive layer IS-CL2 may have a single-layer structure or a multi-layer structure. The conductive layer having the multi-layer structure may include two or more layers including a transparent conductive layer and a metal layer. The conductive layer having the multi-layer structure may include metal layers including (or containing) different metals from each other.

The first and second conductive layers IS-CL1 and IS-CL2 may include at least one of indium tin oxide (ITO), indium zinc oxide (IZO), zinc oxide (ZnO), indium tin zinc oxide (ITZO), PEDOT, metal nanowire, and graphene as the transparent conductive layer. The first and second conductive layers IS-CL1 and IS-CL2 may include molybdenum, silver, titanium, copper, aluminum, and alloys thereof as the metal layer. As an example, each of the first and second conductive layers IS-CL1 and IS-CL2 may have a three-layer structure of titanium/aluminum/titanium. Metals having a relatively high durability and a low reflectance may be applied as (or used as) an outer layer of the conductive layer, and metals having a high electrical conductivity may be applied as (or used as) an inner layer of the conductive layer.

The first conductive layer IS-CL1 and the second conductive layer IS-CL2 may include sensing patterns of the input sensor ISP, to be described later. The sensing patterns may include sensing electrodes and signal lines connected to the sensing electrodes.

Each of the first, second, and third insulating layers IS-IL1, IS-IL2, and IS-IL3 may include an inorganic layer or an organic layer. The inorganic layer may include at least one of aluminum oxide, titanium oxide, silicon oxide, silicon oxynitride, zirconium oxide, and hafnium oxide. However, materials for the first, second, and third insulating layers IS-IL1, IS-IL2, and IS-IL3 are not limited thereto or thereby. According to an embodiment, each of the first and second insulating layers IS-IL1 and IS-IL2 may include organic layer. As an example, each of the first and second insulating layers IS-IL1 and IS-IL2 may include the inorganic layer, and the third sensing insulating layer IS-IL3 may include the organic layer.

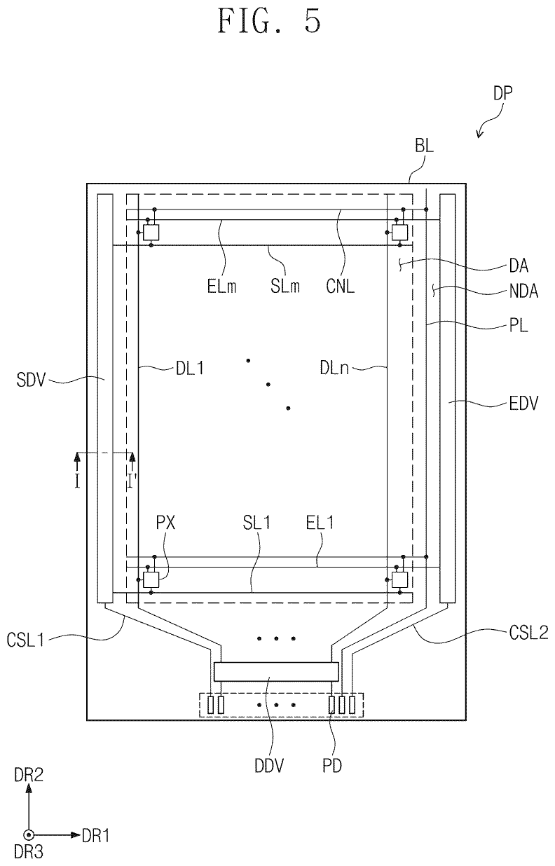

FIG. 5 is a plan view of the display panel DP according to an embodiment of the present disclosure. FIG. 5 shows some of the components of the display panel DP on a plane.

Referring to FIG. 5, the display panel DP may include the base layer BL, a plurality of pixels PX, a plurality of signal lines electrically connected to the pixels PX, a scan driver SDV, a data driver DDV, and an emission driver EDV.

As described above, the base layer BL may have the display area DA and the non-display area NDA. The base layer BL may provide the base surface on which electrical elements and lines of the display panel DP are disposed. In FIG. 5, the base layer BL has a rectangular shape substantially parallel to the first direction DR1 and the second direction DR2 when viewed in a plane; however, the shape of the base layer BL is not limited thereto or thereby. According to an embodiment, the base layer BL may be designed in various ways (e.g., may have various shapes) depending on the structure of the display device DD.

Each of the pixels PX may include a pixel driving circuit configured to include a light emitting element, a plurality of transistors connected to the light emitting element (e.g., a switching transistor, a driving transistor, etc.), and at least one capacitor. Each of the pixels PX may emit light in response to an electrical signal applied thereto. The pixels PX may be arranged in the display area DA; however, this is merely an example. According to an embodiment, thin film transistors of some pixels from among the pixels PX may be disposed in the non-display area NDA, and the pixels are not particularly limited in their location.

Each of the scan driver SDV, the data driver DDV, and the emission driver EDV may be disposed in the non-display area NDA of the display panel DP. According to an embodiment, the scan driver SDV and the emission driver EDV may be disposed in the non-display area NDA to be respectively adjacent to long sides of the base layer BL. The data driver DDV may be disposed in the non-display area NDA to be adjacent to one short side of the base layer BL. However, they are not limited thereto or thereby. According to an embodiment, at least one of the scan driver SDV, the data driver DDV, and the emission driver EDV may be disposed to overlap the display area DA. Therefore, a size of the non-display area NDA may be reduced, and the bezel area of the electronic device may be reduced.

The data driver DDV may be manufactured in an integrated circuit chip form and may be mounted on the non-display area NDA of the display panel DP, however, it should not be limited thereto or thereby. According to an embodiment, the data driver DDV may be electrically connected to the display panel DP after being mounted on a separate flexible circuit board connected to the display panel DP.

According to an embodiment, at least a portion of the non-display area NDA of the display panel DP may be bent. As an example, the display panel DP may be bent such that a portion of the non-display area NDA in which the data driver DDV is disposed may overlap a portion of the display panel DP in which the display area DA is defined when viewed in a plane; however, the display panel DP is not limited thereto or thereby. According to an embodiment, the data driver DDV may be mounted on a separate flexible circuit board, and the flexible circuit board may be bent to be connected to one end of the display panel DP. Accordingly, the bezel area of the display device DD may be reduced.

The signal lines may include a plurality of scan lines SL1 to SLm, a plurality of data lines DL1 to DLn, a plurality of emission lines EL1 to ELm, first and second control lines CSL1 and CSL2, a power line PL, and a plurality of connection lines CNL. Each of m and n is a natural number.

Each of the pixels PX may be connected to a corresponding scan line from among the scan lines SL1 to SLm, a corresponding data line from among the data lines DL1 to DLn, and a corresponding emission line from among the emission lines EL1 to ELm. Other types of signal lines may be provided in the display panel DP depending on the configuration of the pixel driving circuit of the pixels PX.

The scan lines SL1 to SLm may extend in the first direction DR1 and may be connected to the scan driver SDV. The data lines DL1 to DLn may extend in the second direction DR2 and may be connected to the data driver DDV. The emission lines EL1 to ELm may extend in the first direction DR1 and may be connected to the emission driver EDV.

The power line PL may extend in the second direction DR2 and may be disposed in the non-display area NDA. The power line PL may be disposed between the display area DA and the emission driver EDV, however, it is not limited thereto or thereby. For example, in another embodiment, the power line PL may be disposed between the display area DA and the scan driver SDV.

The connection lines CNL may extend in the first direction DR1 and may be arranged in (e.g., may be adjacent to each other in) the second direction DR2. The connection lines CNL may be connected to the power line PL and the pixels PX. The connection lines CNL may be disposed on a layer different from a layer on which the power line PL is disposed and may be electrically connected to the power line PL; however, they are not limited thereto or thereby. According to an embodiment, the connection lines CNL may be disposed on the same layer as the power line PL and may be provided (or formed) integrally with the power line PL. A first voltage may be applied to the pixels PX via the power line PL and the connection lines CNL connected to the power line PL.

The first control line CSL1 may be connected to the scan driver SDV. The second control line CSL2 may be connected to the emission driver EDV.

The pads PD may be disposed adjacent to a lower end of the non-display area NDA. The pads PD may be disposed closer to the lower end of the display panel DP than the data driver DDV is (e.g., the pads PD may be disposed between the lower end of the display panel DP and the data driver DDV). The pads PD may be arranged in the first direction DR1. The display device DD may include a circuit board including a timing controller to control an operation of the scan driver SDV, the data driver DDV, and the emission driver EDV and a voltage generator to generate a voltage, and the pads PD may be connected to the circuit board of the display device DD.

Each of the pads PD may be connected to a corresponding signal line from among the signal lines. The power line PL and the first and second control lines CSL1 and CSL2 may be connected to the pads PD. The data lines DL1 to DLn may be connected to corresponding pads PD via the data driver DDV. As an example, the data lines DL1 to DLn may be connected to the data driver DDV, and the data driver DDV may be connected to the pads PD respectively corresponding to the data lines DL1 to DLn.

The scan driver SDV may generate a plurality of scan signals in response to a scan control signal. The scan signals may be applied to the pixels PX via the scan lines SL1 to SLm. The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive the data voltages in response to the scan signals. The pixels PX may emit light having a luminance corresponding to the data voltages in response to the emission signals, and thus, the image may be displayed. An emission time of the pixels PX may be controlled by the emission signals. Accordingly, the display panel DP may display the image through the display area DA by using the pixels PX.

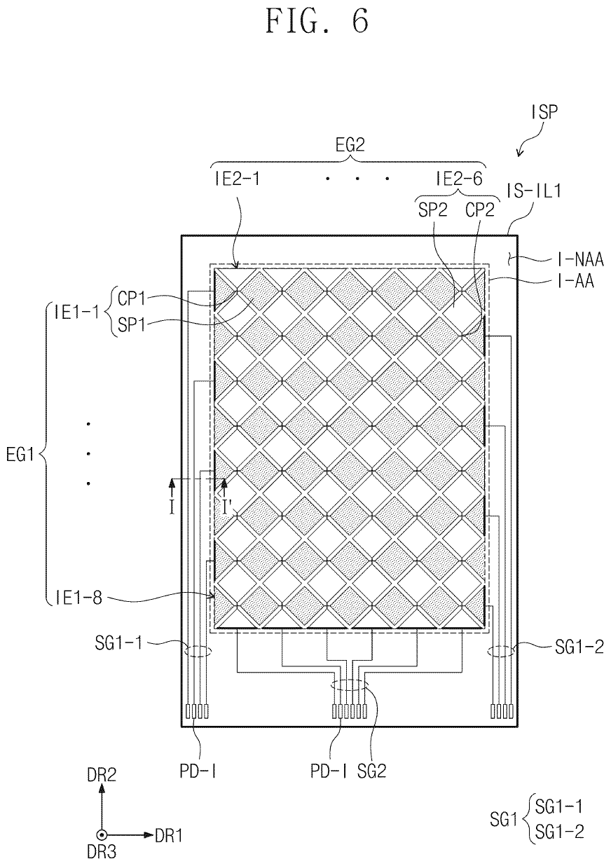

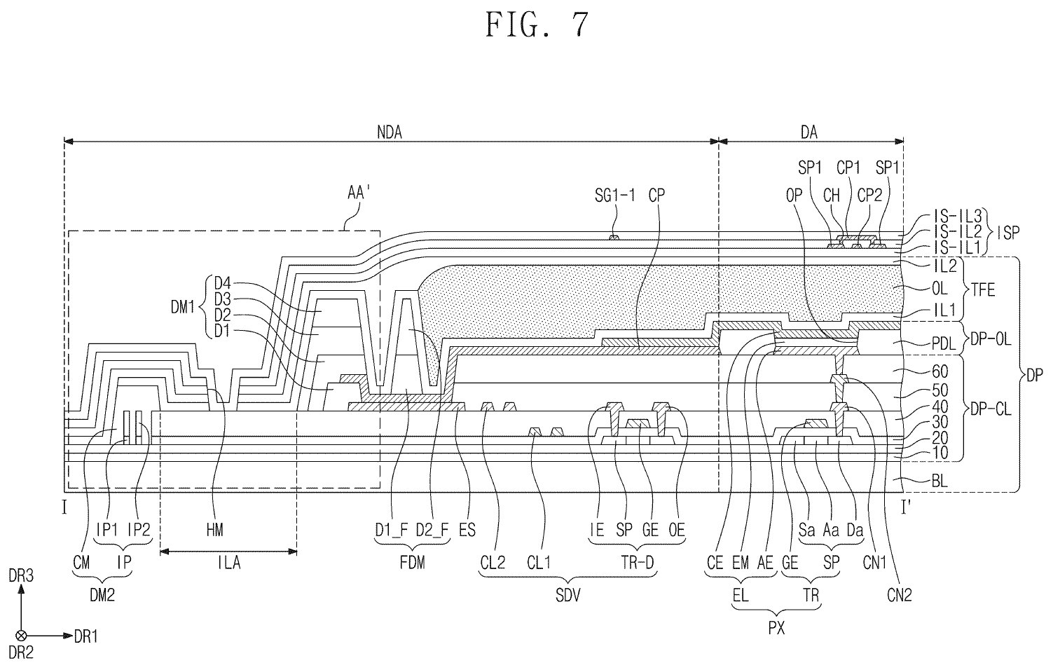

FIG. 6 is a plan view of the input sensor ISP according to an embodiment of the present disclosure. FIG. 6 shows some of components of the input sensor ISP on a plane.

Referring to FIGS. 4 and 6, the input sensor ISP may include the first sensing insulating layer IS-IL1, the first conductive layer IS-CL1, the second sensing insulating layer IS-IL2, the second conductive layer IS-CL2, and the third sensing insulating layer IS-IL3. The first conductive layer IS-CL1 and the second conductive layer IS-CL2 of the input sensor ISP may include a first electrode group EG1, a second electrode group EG2, a first sensing signal line group SG1 connected to the first electrode group EG1, and a second sensing signal line group SG2 connected to the second electrode group EG2. The first conductive layer EG1 and the second conductive layer EG2 may be disposed in a sensing area I-AA, and the first sensing signal line group SG1 and the second sensing signal line group SG2 may be disposed in a line area I-NAA.

The shape of the first electrode group EG1 and the shape of the second electrode group EG2 shown in FIG. 6 are merely examples, and the shapes of the first and second electrode groups EG1 and EG2 may be designed in various ways depending on the structure and use of the display device DD.

The first sensing insulating layer IS-IL1 may provide a base surface on which the electrodes and the lines of the input sensor ISP are disposed. However, according to another embodiment, the first sensing insulating layer IS-IL1 of the input sensor ISP may be omitted, and in such an embodiment, the electrodes and the lines of the input sensor ISP may be disposed on the base surface provided by the display panel DP. FIG. 6 shows an embodiment in which the first sensing insulating layer IS-IL1 has a rectangular shape parallel to each of the first direction DR1 and the second direction DR2 when viewed in a plane; however, the shape of the first sensing insulating layer IS-IL1 is not limited to the rectangular shape. The shape of the first sensing insulating layer IS-IL1 may be designed in various ways according to the shape of the base layer BL (see, e.g., FIG. 5) of the display panel DP (see, e.g., FIG. 5).

The first sensing insulating layer IS-IL1 may have the sensing area I-AA and the line area I-NAA. The sensing area I-AA may be an area in which the external input provided from the outside of the display device DD is sensed. The line area I-NAA may be an area in which the lines providing electrical signals to activate the sensing area I-AA are disposed. The sensing area I-AA may correspond to the display area DA of the display panel DP (see, e.g., FIG. 5), and the line area I-NAA may correspond to the non-display area NDA of the display panel DP (see, e.g., FIG. 5).

In the present embodiment, the input sensor ISP may be, but is not limited to, a sensor operated in a capacitive mode. The input sensor ISP may obtain information on the external input based on a variation in capacitance between the first electrode group EG1 and the second electrode group EG2. One group of the first electrode group EG1 and the second electrode group EG2 may receive a driving signal, and the other group of the first electrode group EG1 and the second electrode group EG2 may output a variation in capacitance between the first electrode group EG1 and the second electrode group EG2 as a sensing signal. However, this is merely an example. The driving manner of the input sensor ISP of the display device DD is not limited thereto or thereby.

The first electrode group EG1 may include first sensing electrodes IE1-1, IE1-2, IE1-3, IE1-4, IE1-5, IE1-6, IE1-7, and IE1-8. The second electrode group EG2 may include second sensing electrodes IE2-1, IE2-2, IE2-3, IE2-4, IE2-5, and IE2-6. FIG. 6 shows an embodiment in which the first electrode group EG1 includes eight first sensing electrodes IE1-1 to IE1-8 and the second electrode group EG2 includes six second sensing electrodes IE2-1 to IE2-6; however, the number of the sensing electrodes is not limited thereto or thereby.

The first sensing electrodes IE1-1 to IE1-8 may extend in the first direction DR1. Each of the first sensing electrodes IE1-1 to IE1-8 may form one row substantially parallel to the first direction DR1. The first sensing electrodes IE1-1 to IE1-8 may be arranged in the second direction DR2.

Each of the first sensing electrodes IE1-1 to IE1-8 may include first sensor portions SP1 and first connection portions CP1. The first sensor portions SP1 forming one first sensing electrode may be arranged in the first direction DR1. Each of the first connection portions CP1 may connect two first sensor portions SP1 adjacent to each other in the first direction DR1 from among the first sensor portions SP1. The first sensor portions SP1 may be disposed on a different layer from the first connection portions CP1 and may be connected to the first connection portions CP1. As an example, the first sensor portions SP1 may be disposed on the first sensing insulating layer IS-IL1 and may be included in the first conductive layer IS-CL1, and the first connection portions CP1 may be disposed on the second sensing insulating layer IS-IL2 and may be included in the second conductive layer IS-CL2.

The second sensing electrodes IE2-1 to IE2-6 may extend in the second direction DR2. Each of the second sensing electrodes IE2-1 to IE2-6 may form one column substantially parallel to the second direction DR2. The second sensing electrodes IE2-1 to IE2-6 may be arranged in the first direction DR1.

Each of the second sensing electrodes IE2-1 to IE2-6 may include second sensor portions SP2 and second connection portions CP2. The second sensor portions SP2 forming one second sensing electrode may be arranged in the second direction DR2. Each of the second connection portions CP2 may connect two second sensor portions SP2 adjacent to each other in the second direction DR2 from among the second sensor portions SP2. The second sensor portions SP2 may be disposed on the same layer as the second connection portions CP2 and may be provided (or formed) integrally with the second connection portions CP2. As an example, the second sensor portions SP2 and the second connection portions CP2 may be disposed on the first sensing insulating layer IS-IL1 and may be included in the first conductive layer IS-CL1. For example, the first connection portions CP1 may cross the second connection portions CP2 while being electrically insulated from the second connection portions CP2 when viewed in the plane.

A length or a size of the first sensing electrodes IE1-1 to IE1-8 and the second sensing electrodes IE2-1 to IE2-6 may be changed depending on an arrangement of the sensing electrodes and a size of the sensing area I-AA.

Each of the first sensor portions SP1, the second sensor portions SP2, the first connection portions CP1, and the second connection portions CP2 may be conductive. Each of the first sensor portions SP1, the second sensor portions SP2, the first connection portions CP1, and the second connection portions CP2 may be formed from the first conductive layer IS-CL1 or the second conductive layer IS-CL2.

FIG. 6 shows an embodiment in which the first sensor portions SP1 and the second sensor portions SP2 each have a lozenge shape; however, this is merely an example. According to another embodiment, each of the first sensor portions SP1 and the second sensor portions SP2 may have a variety of shapes. Also, FIG. 6 shows an embodiment in which each of the first connection portions CP1 have a straight shape, however, this is merely an example. According to another embodiment, each of the first connection portions CP1 may be changed into a curved line form having an inverted “V” shape (e.g., “A”) and/or a curved line form having a shape “v” similar to the V shape offset from (e.g., so as not to overlap) the second connection portions CP2.

The first sensing electrodes IE1-1 to IE1-8 and the second sensing electrodes IE2-1 to IE2-6 may overlap the display area DA of the display panel DP (see, e.g., FIG. 5) when viewed in a plane. Accordingly, the first sensing electrodes IE1-1 to IE1-8 and the second sensing electrodes IE2-1 to IE2-6 may include an optically transparent conductive material. In addition, the first sensing electrodes IE1-1 to IE1-8 and the second sensing electrodes IE2-1 to IE2-6 may form (or may be arranged in) a mesh pattern. The first sensing electrodes IE1-1 to IE1-8 and the second sensing electrodes IE2-1 to IE2-6 may be provided in various ways and are not particularly limited as long as a visibility of the image displayed through the display panel DP is not deteriorated.

The first sensing signal line group SG1 may include the same number of first sensing signal lines as the number of the first sensing electrodes IE1-1 to IE1-8. The first sensing signal lines may be connected to one end of both ends (e.g., opposite ends) of the first sensing electrodes IE1-1 to IE1-8. As an example, the first sensing signal line group SG1 may be divided into two groups that are respectively defined as a first signal line group SG1-1 disposed at one side in the line area I-NAA and a second signal line group SG1-2 disposed at the other side in the line area I-NAA.

The first signal line group SG1-1 may be connected to a left side of some sensing electrodes from among the first sensing electrodes IE1-1 to IE1-8. The second signal line group SG1-2 may be connected to a right side of the remaining sensing electrodes that are not connected to the first signal line group SG1-1 from among the first sensing electrodes IE1-1 to IE1-8. The first signal line group SG1-1 and the second signal line group SG1-2 may be spaced apart from each other with the sensing area I-AA interposed therebetween in the first direction DR1. When the first sensing signal lines of the first sensing signal line group SG1 are divided into two groups to be disposed at both sides, a width of the line area I-NAA may be reduced.

For example, the first signal line group SG1-1 may be electrically connected to the sensing electrodes forming odd-numbered rows from among the first sensing electrodes IE1-1 to IE1-8, and the second signal line group SG1-2 may be electrically connected to the sensing electrodes forming even-numbered rows from among the first sensing electrodes IE1-1 to IE1-8.

However, the arrangement of the first sensing signal lines of the first sensing signal line group SG1 are not limited thereto or thereby. As an example, the first sensing signal lines may be connected to both ends of the first sensing electrodes IE1-1 to IE1-8. According to an embodiment, all of the first sensing signal lines of the first sensing signal line group SG1 may be connected to left sides of the first sensing electrodes IE1-1 to IE1-8 or right sides of the first sensing electrodes IE1-1 to IE1-8 without being divided into two groups.

The second sensing signal line group SG2 may include the same number of second sensing signal lines as the number of the second sensing electrodes IE2-1 to IE2-6. The second sensing signal lines may be connected to one end of both ends (e.g., opposite ends) of the second sensing electrodes IE2-1 to IE2-6. Referring to FIG. 6, the second sensing signal lines of the second sensing signal line group SG2 may be connected to lower ends of the second sensing electrodes IE2-1 to IE2-6, respectively.

Each of the sensing signal lines of the first sensing signal line group SG1 and the second sensing signal line group SG2 may be connected to a corresponding sensing pad PD-I from among sensing pads PD-I arranged in the first direction DR1. The sensing pads PD-I may be connected to the same circuit board to which the display panel DP is connected, or the sensing pads PD-I may be connected to a circuit board separated from the circuit board connected to the display panel DP and may be independently controlled.

The sensing pads PD-I may be disposed on a different layer from the pads PD of the display panel DP; however, they are not limited thereto or thereby. According to an embodiment, the sensing pads PD-I may be disposed on the same layer as the pads PD of the display panel DP, and ends of the sensing signal lines of the input sensor ISP may be electrically connected to corresponding sensing pads PD-I through contact holes (e.g., contact openings), respectively.

FIG. 7 is a cross-sectional view of the display panel and the input sensor taken along the line I-I′ in FIG. 5 according to an embodiment of the present disclosure. FIG. 7 shows a cross-section of the display panel DP and the input sensor ISP in the display area DA and the non-display area NDA adjacent to the display area DA. In FIG. 7, the same reference numerals denote the same elements in FIGS. 1 to 6, and thus, detailed descriptions of the same elements will be omitted.

Referring to FIG. 7, the display panel DP may include the base layer BL, the circuit layer DP-CL, the display element layer DP-OL, and the encapsulation layer TFE. Details of the components of the display panel DP described above may be applied to the components of the display panel DP, as shown in, for example, FIG. 7.

The base layer BL may include a glass substrate, a metal substrate, a polymer substrate, or an organic/inorganic composite material substrate. The base layer BL may include a synthetic resin layer. As an example, the synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin; however, materials for the base layer BL are not limited thereto or thereby.

The circuit layer DP-CL may be disposed on the base layer BL. The circuit layer DP-CL may include at least one insulating layer, a conductive pattern, and a semiconductor pattern. An insulating layer, a semiconductor layer, and a conductive layer may be formed on the base layer BL by a coating or depositing process during a manufacturing process of the display panel DP. Then, the insulating layer, the semiconductor layer, and the conductive layer may be selectively patterned through several photolithography processes. After the processes are completed, the semiconductor pattern, the conductive pattern, and the signal line included in the circuit layer DP-CL may be formed.

FIG. 7 shows first, second, third, fourth, fifth, and sixth insulating layers 10, 20, 30, 40, 50, and 60 included in the circuit layer DP-CL, the semiconductor pattern, and the conductive pattern. However, the cross-section of the circuit layer DP-CL as shown in FIG. 7 is merely an example, and the stacked structure of the circuit layer DP-CL may be changed in various ways depending on processes, a process method, or the configuration of the pixel.

The first insulating layer 10 may be disposed on the base layer BL. The first insulating layer 10 may include an inorganic layer and may be provided on the base layer BL as a barrier layer. The first insulating layer 10 provided as the barrier layer may prevent a foreign substance from entering thereto from the outside. The first insulating layer 10 may include at least one of a silicon oxide layer and a silicon nitride layer. According to an embodiment, the first insulating layer 10 provided as the barrier layer may include silicon oxide layers and silicon nitride layers alternately stacked with the silicon oxide layers.

The second insulating layer 20 may be disposed on the first insulating layer 10. The second insulating layer 20 may include an inorganic layer and may be provided as a buffer layer on the base layer BL. The second insulating layer 20 provided as the buffer layer may increase an adhesive force between the base layer BL and the semiconductor pattern or the conductive pattern. The second insulating layer 20 may include at least one of a silicon oxide layer and a silicon nitride layer, and the second insulating layer 20 provided as the buffer layer may include silicon oxide layers and silicon nitride layers alternately stacked with the silicon oxide layers.

The pixels PX may be disposed on the second insulating layer 20. Each of the pixels PX may have an equivalent circuit including a transistor TR, at least one capacitor, and a light emitting element EL, and the equivalent circuit of the pixel PX may be changed in various ways. The semiconductor pattern may be arranged over (e.g., may be arranged with a specific rule or pattern over) the pixels PX according to the equivalent circuit of the pixel PX. FIG. 7 shows some components of the pixel PX as a representative example.

The transistor TR may include a semiconductor pattern SP and a gate GE. The semiconductor pattern SP may be disposed on the second insulating layer 20. The semiconductor pattern SP may include a silicon semiconductor and may include a crystalline silicon semiconductor, a polysilicon semiconductor, or an amorphous silicon semiconductor; however, it is not limited thereto or thereby. The semiconductor pattern SP may include an oxide semiconductor. The semiconductor pattern SP may include a variety of materials as long as the semiconductor pattern SP has a semiconductor property, and it is not particularly limited.

A source Sa, a drain Da, and a channel Aa of the transistor TR may be formed from the semiconductor pattern SP. The semiconductor pattern SP may have a plurality of areas distinguished from each other depending on their respective conductivity. As an example, the semiconductor pattern SP may have different electrical properties depending on whether or not it is doped, whether it is doped with an N-type dopant or a P-type dopant, or whether a metal oxide is reduced. An area in which the metal oxide is reduced (hereinafter, referred to as a reduced area) has a conductivity greater than that of an area in which the metal oxide is not reduced. A portion of the semiconductor pattern (hereinafter, referred to as a non-reduced area), which has a relatively high conductivity, may act as an electrode or a signal line and may correspond to the source Sa and the drain Da of the transistor TR. A non-doped or non-reduced portion with a relatively low conductivity may correspond to the channel Aa (or an active area) of the transistor TR.

The semiconductor pattern SP may have a first region with high conductivity and a second region with low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or may be doped at a concentration lower than the first region.

The third to sixth insulating layers 30 to 60 may be stacked on the semiconductor pattern SP. The third to sixth insulating layers 30 to 60 may include an inorganic layer or an organic layer. As an example, the inorganic layer may include at least one of aluminum oxide, titanium oxide, silicon oxide, silicon nitride, silicon oxynitride, zirconium oxide, and hafnium oxide. The organic layer may include a phenolic-based polymer, an acrylic-based polymer, an imide-based polymer, an aryl ether-based polymer, an amide-based polymer, a fluorine-based polymer, a p-xylene-based polymer, a vinyl alcohol-based polymer, or blends thereof. However, the material for the insulating layer is not limited thereto or thereby.

The third insulating layer 30 may be disposed on the second insulating layer 20 and may cover the semiconductor pattern SP. The third insulating layer 30 may be disposed between the semiconductor pattern SP and the gate GE of the transistor TR. According to an embodiment, the third insulating layer 30 may be an inorganic layer having a single-layer or multiple-layer structure.

The gate GE may be disposed on the third insulating layer 30. The gate GE may be a portion of the conductive pattern of the circuit layer DP-CL. When viewed in a plane, the gate GE may overlap the channel Aa of the transistor TR. The gate GE may act as a mask in a process of doping the semiconductor pattern SP.

The transistor TR shown in FIG. 7 is merely an example, and the source Sa or the drain Da may be electrodes formed independently from the semiconductor pattern SP. In such an embodiment, the source Sa and the drain Da may be in contact with the semiconductor pattern SP or may be connected to the semiconductor pattern SP after penetrating through (or passing through) the insulating layer. According to an embodiment, the gate GE may be disposed under the semiconductor pattern SP. The transistor TR may have various structures and should not be particularly limited.

The fourth insulating layer 40 may be disposed on the third insulating layer 30 and may cover the gate GE. According to an embodiment, the fourth insulating layer 40 may be an inorganic layer having a single-layer or multiple-layer structure. The fifth insulating layer 50 may be disposed on the fourth insulating layer 40. According to an embodiment, the fifth insulating layer 50 may be an organic layer having a single-layer or multiple-layer structure.

A first connection electrode CN1 may be disposed on the fourth insulating layer 40. A second connection electrode CN2 may be disposed on the fifth insulating layer 50. The first connection electrode CN1 may be electrically connected to the semiconductor pattern SP via a contact hole (e.g., a contact opening) defined through the third insulating layer 30 and the fourth insulating layer 40. The second connection electrode CN2 may be electrically connected to the first connection electrode CN1 via a contact hole (e.g., a contact opening) defined through the fifth insulating layer 50. The sixth insulating layer 60 may be disposed on the fifth insulating layer 50 and may cover the second connection electrode CN2.

At least one of the first connection electrode CN1 and the second connection electrode CN2 may be omitted. According to an embodiment, an additional connection electrode may be provided to connect the light emitting element EL and the transistor TR. An electrical connection method between the light emitting element EL and the transistor TR may be changed in various ways depending on the number of the insulating layers disposed between the light emitting element EL and the transistor TR and is not particularly limited.

The circuit layer DP-CL may include the scan driver SDV disposed on the base layer BL. FIG. 7 schematically shows the cross-section of the scan driver SDV disposed in the non-display area NDA; however, the present embodiment should not be limited thereto or thereby. According to another embodiment, at least some components of the scan driver SDV may be disposed in the display area DA and may overlap the light emitting element EL.

The scan driver SDV may include a driving transistor TR-D, first signal lines CL1, and second signal lines CL2. The driving transistor TR-D may be disposed on the second insulating layer 20. The driving transistor TR-D may be formed on the same layer as the transistor TR of the pixel PX; however, it should not be limited thereto or thereby. The driving transistor TR-D may be disposed on a layer different from the transistor TR of the pixel PX.

The driving transistor TR-D may include a semiconductor pattern SP, a gate GE, a source IE, and a drain OE. Each of the gate GE, the source IE, and the drain OE may be formed as an electrode and may be independently formed from the semiconductor pattern SP. The source IE and the drain OE may be disposed on the fourth insulating layer 40 and may be connected to the semiconductor pattern SP via contact holes (e.g., a contact openings) defined through the third insulating layer 30 and the fourth insulating layer 40.

The above-described structure is merely an example, and according to another embodiment, the driving transistor TR-D may have the same structure as that of the transistor TR of the pixel PX. In such an embodiment, because the driving transistor TR-D may be formed through the same process as the transistor TR of the pixel PX, processes may be simplified and a process cost may be reduced.

The first signal lines CL1 and the second signal lines CL2 may be disposed on different layers from each other. According to an embodiment, the first signal lines CL1 may be disposed on the same layer as the gate GE of the driving transistor TR-D, and the second signal lines CL2 may be disposed on the same layer as the source IE or the drain OE of the driving transistor TR-D. The first signal lines CL1 and the second signal lines CL2 may electrically connect the driving transistor TR-D to other components of the scan driver SDV. This is merely an example, and according to another embodiment, one of the first signal lines CL1 and the second signal lines CL2 may be omitted.

The display element layer DP-OL may be disposed on the circuit layer DP-CL. The display element layer DP-OL may include the light emitting element EL and a pixel definition layer PDL. The light emitting element EL may be electrically connected to the transistor TR to form the pixel PX. The light emitting element EL may be disposed in the display area DA and may emit light. As an example, the light emitting element EL may include an organic light emitting element, a quantum dot light emitting element, a micro-LED, or a nano-LED; however, it is not limited thereto or thereby. According to an embodiment, the light emitting element EL may include various embodiments as long as light may be generated or an amount of light may be controlled according to an electrical signal.

The light emitting element EL may include a first electrode AE, a light emitting layer EM, and a second electrode CE. The first electrode AE may be disposed on the sixth insulating layer 60. The first electrode AE may be connected to the second connection electrode CN2 via a contact hole (e.g., a contact opening) defined through the sixth insulating layer 60.

The pixel definition layer PDL may be disposed on the first electrode AE and the sixth insulating layer 60 and may expose at least a portion of the first electrode AE. For example, a light emitting opening OP may be defined through the pixel definition layer PDL to expose at least the portion of the first electrode AE.

The pixel definition layer PDL may be formed of a polymer resin. As an example, the pixel definition layer PDL may include a polyacrylate-based resin or a polyimide-based resin. The pixel definition layer PDL may include an inorganic material in addition to the polymer resin. According to an embodiment, the pixel definition layer PDL may include an inorganic material. As an example, the pixel definition layer PDL may include silicon nitride (SiNₓ), silicon oxide (SiOₓ), or silicon oxynitride (SiOₓN_{y}).

The pixel definition layer PDL may include a light absorbing material. The pixel definition layer PDL may include a black coloring agent. The black coloring agent may include a black pigment or a black dye. The black coloring agent may include a metal material, such as carbon black, chrome, etc., or an oxide thereof.

The light emitting layer EM may be disposed on the first electrode AE. The light emitting layer EM may be disposed in an area corresponding to the light emitting opening OP in the pixel definition layer PDL. The light emitting layer EM may provide (e.g., may emit) light with a predetermined color. The light emitting layer EM may include an organic light emitting material and/or an inorganic light emitting material. As an example, the light emitting layer EM may include a fluorescent or phosphorescent material, an organometallic complex light emitting material, or a quantum dot.

The second electrode CE may be disposed on the light emitting layer EM. The second electrode CE may be commonly disposed over the pixels PX. The second electrode CE may receive a common voltage, and the second electrode CE may be referred to as a common electrode.

The light emitting element EL may further include light emitting functional layers disposed between the first electrode AE and the second electrode CE. As an example, the light emitting element EL may include a hole transport layer or a hole injection layer disposed between the first electrode AE and the light emitting layer EM, and an electron transport layer or an electron injection layer disposed between the light emitting layer EM and the second electrode CE.

The first voltage may be applied to the first electrode AE via the transistor TR, and the common voltage may be applied to the second electrode CE. Holes and electrons, which are injected into the light emitting layer EM, may be recombined with each other to generate excitons. The light emitting element EL may emit light through the display area DA when the excitons return to a ground state from an excited state.

The display panel DP may include a power pattern ES and a conductive pattern CP connected to the second electrode CE. The power pattern ES may be disposed in the non-display area NDA, and the conductive pattern CP may be disposed on the power pattern ES. The conductive pattern CP may extend from the power pattern ES to the display area DA. The conductive pattern CP may electrically connect the power pattern ES to the second electrode CE, and the power pattern ES may supply a power voltage to the second electrode CE.

The encapsulation layer TFE may be disposed on the display element layer DP-OL and may cover the light emitting element EL. The encapsulation layer TFE may encapsulate the light emitting element EL. The encapsulation layer TFE may include at least one insulating layer, and the insulating layer may be an inorganic layer or an organic layer. According to an embodiment, the encapsulation layer TFE may include a plurality of insulating layers, at least one from among the insulating layers may be the organic layer, and at least another one from among the insulating layers may be the inorganic layer. FIG. 7 shows an embodiment in which the encapsulation layer TFE includes a first inorganic layer IL1, an organic layer OL, and a second inorganic layer IL2 as an example. The first inorganic layer IL1 may be disposed on the second electrode CE. The organic layer OL may be disposed on the first inorganic layer IL1. The second inorganic layer IL2 may be disposed on the organic layer OL and may cover the organic layer OL. However, a stacked structure of the encapsulation layer TFE is not limited thereto or thereby.

The first inorganic layer IL1 and the second inorganic layer IL2 may protect the light emitting element EL from moisture and/or oxygen. As an example, the first inorganic layer IL1 and the second inorganic layer IL2 may include at least one of aluminum oxide, titanium oxide, silicon oxide, silicon nitride, silicon oxynitride, zirconium oxide, and hafnium oxide; however, they are not limited thereto or thereby. The first inorganic layer IL1 and the second inorganic layer IL2 may extend from the display area DA and may be disposed in the non-display area NDA. The first inorganic layer IL1 may cover the power pattern ES and the conductive pattern CP, and the second inorganic layer IL2 may be in contact with the first inorganic layer IL1 in the non-display area NDA.

The organic layer OL may protect the light emitting element EL from a foreign substance, such as dust particles. As an example, the organic layer OL may include an acrylic-based resin; however, the material of the organic layer OL is not limited thereto or thereby. The organic layer OL may be formed by providing a liquid polymer resin on the first inorganic layer IL1 and curing the liquid polymer resin. The liquid polymer resin may be formed by a vapor deposition method, a printing method, or a slit coating method; however, it is not limited thereto or thereby. According to an embodiment, the organic layer OL may be formed by an inkjet process.

The input sensor ISP may be disposed on the display panel DP. The input sensor ISP may include the first, second, and third sensing insulating layers IS-IL1, IS-IL2, and IS-IL3 and the first and conductive layers IS-CL1 and IS-CL2 as shown in, for example, FIG. 4.

The first sensing insulating layer IS-IL1 may be disposed on the encapsulation layer TFE. The first sensing insulating layer IS-IL1 may be formed through successive processes after the encapsulation layer TFE is formed, and the first sensing insulating layer IS-IL1 may be in contact with an uppermost layer of the encapsulation layer TFE. Referring to FIG. 7, the first sensing insulating layer IS-IL1 may be in contact with the second inorganic layer IL2 provided as the uppermost layer of the encapsulation layer TFE. The first sensing insulating layer IS-IL1 may extend from the display area DA and may be disposed in the non-display area NDA.

The first conductive layer IS-CL1 (see, e.g., FIG. 4) and the second conductive layer IS-CL2 (see, e.g., FIG. 4) of the input sensor ISP may include the sensing electrodes or the sensing signal lines shown in FIG. 6. FIG. 7 schematically shows a cross-section of the components of the input sensor ISP, and the following descriptions are based on the cross-section shown in FIG. 7; however, the arrangement of the components of the input sensor ISP are not limited thereto or thereby.

The first sensor portions SP1 and the second connection portion CP2 may be formed from the first conductive layer IS-CL1 and may be disposed on the first sensing insulating layer IS-IL1. The second sensor portions SP2 may also be disposed on the second sensing insulating layer IS-IL2. The first sensor portions SP1, the second sensor portions SP2, and the second connection portion CP2 may be disposed to overlap the display area DA. The second sensing insulating layer IS-IL2 may be disposed on the first sensing insulating layer IS-IL1 and may cover the first sensor portions SP1, the second sensor portions SP2, and the second connection portion CP2. The second sensing insulating layer IS-IL2 may extend from the display area DA and may be disposed in the non-display area NDA.

The first connection portions CP1 may be formed from the second conductive layer IS-CL2 and may be disposed on the second sensing insulating layer IS-IL2. The first connection portions CP1 may be electrically connected to the first sensor portions SP1 via a contact hole (e.g., a contact opening) CH defined through the second sensing insulating layer IS-IL2. The first connection portions CP1 may overlap the second connection portions CP2 when viewed in the plane and may be electrically insulated from the second connection portions CP2 by the second sensing insulating layer IS-IL2.

The sensor portions and the connection portions of the input sensor ISP may form a mesh pattern and may be disposed in an area corresponding to an area in which the pixel definition layer PDL is disposed. Accordingly, the input sensor ISP may not exert influence on (e.g., may not reduce) light emission efficiency of the light emitting element EL; however, it is not limited thereto or thereby. According to another embodiment, the input sensor ISP may have a single-shaped pattern overlapping the light emitting elements EL and may include a transparent conductive material.

A portion of the second conductive layer IS-CL2 (see, e.g., FIG. 4) may form the sensing signal lines. FIG. 7 shows a portion of the sensing signal lines of the above-described first sensing signal line group SG1-1 as an example. The sensing signal lines may be disposed on the second sensing insulating layer IS-IL2; however, they are not limited thereto or thereby. According to an embodiment, the sensing signal lines may be a portion of the first conductive layer IS-CL1. The sensing signal lines may be disposed in the non-display area NDA.

The third sensing insulating layer IS-IL3 may be disposed on the second sensing insulating layer IS-IL2 and may cover the second connection portions CP2 and the sensing signal lines. The third sensing insulating layer IS-IL3 may extend from the display area DA and may also be disposed in the non-display area NDA.

The conductive pattern CP may be disposed between the sensing signal lines and the scan driver SDV and may overlap the sensing signal lines and the scan driver SDV when viewed in a plane. The conductive pattern CP may act as a shielding electrode. For example, the conductive pattern CP may prevent a parasitic capacitance from occurring between the sensing signal lines and the scan driver SDV. Accordingly, a phenomenon in which a signal applied to the sensing signal lines is changed (e.g., is affected) by the scan driver SDV and noise occurs may be reduced or avoided.

The display panel DP may include a flow control dam FDM, a first dam DM1, and a second dam DM2. The flow control dam FDM, the first dam DM1, and the second dam DM2 may be disposed in the non-display area NDA.

The flow control dam FDM may be disposed outside the organic layer OL. The flow control dam FDM may control a flow of the organic layer OL toward an outer edge of the base layer BL. The flow control dam FDM may be covered by the first inorganic layer IL1. FIG. 7 shows a structure in which the flow control dam FDM disposed on the power pattern ES as an example; however, the present disclosure is not limited thereto or thereby. According to another embodiment, the flow control dam FDM may be disposed closer to an outer side of the non-display area NDA than the power pattern ES is and may not overlap the power pattern ES. For example, a position of the flow control dam FDM is not limited as long as the flow of the organic layer OL is controlled.

The flow control dam FDM may have a multi-layer structure. As an example, the flow control dam FDM may include a first layer D1_F and a second layer D2_F. At least one of the first and second layers D1_F and D2_F included in the flow control dam FDM may be formed in a process of forming the insulating layers 10, 20, 30, 40, 50, and 60 or the pixel definition layer PDL of the circuit layer DP-CL. As an example, the first layer D1_F may be formed through the same process as the sixth insulating layer 60, and the second layer D2_F may be formed through the same process as the pixel definition layer PDL; however, these are merely examples. According to another embodiment, the flow control dam FDM may have a single-layer structure or may have a multi-layer structure including more layers than as shown in FIG. 7.

The first dam DM1 may be disposed outside the flow control dam FDM. The first dam DM1 may be covered by the first inorganic layer IL1. FIG. 7 shows the structure in which the first dam DM1 overlaps a portion of the power pattern ES; however, the present disclosure is not limited thereto or thereby. According to an embodiment, the first dam DM1 may be disposed closer to the outer side of the non-display area NDA than the power pattern ES is and may not overlap the power pattern ES. For example, a position of the first dam DM1 is not limited.

The first dam DM1 may have a multi-layer structure. As an example, the first dam DM1 may include a first layer D1 formed through the same process as the fifth insulating layer 50, a second layer D2 formed through the same process as the sixth insulating layer 60, a third layer D3 formed through the same process as the pixel definition layer PDL, and a fourth layer D4 formed through a separate process; however, this is merely an example. According to an embodiment, at least a portion of the first dam DM1 may be concurrently (e.g., may be substantially simultaneously) formed with the insulating layers 10, 20, 30, 40, 50, and 60 or the pixel definition layer PDL of the circuit layer DP-CL. In addition, the first dam DM1 may have a single-layer structure or may have a multi-layer structure including more layers than as shown in FIG. 7.

The second dam DM2 may be disposed outside the first dam DM1. The second dam DM2 may be spaced apart from the first dam DM1 in a direction away from the display area DA from a boundary between the display area DA and the non-display area NDA, for example, in a direction opposite to the first direction DR1. A portion of the second dam DM2 may be covered by the first inorganic layer IL1, and the other portion of the second dam DM2 may be covered by the second inorganic layer IL2; however, this is merely an example. According to an embodiment, the second dam DM2 may be covered by the first inorganic layer IL1. For example, the second dam DM2 is not limited as long as the second dam DM is covered by the inorganic layer.

The second dam DM2 may alleviate impacts that occur outside of the display device DD (see, e.g., FIG. 1) and, thus, may prevent cracks from occurring in the insulating layer. The second dam DM2 may include a plurality of insulating patterns IP and a cover member CM. The insulating patterns IP may be arranged spaced apart from each other in the first direction DR1 and may extend in the second direction DR2. A space may be defined between the insulating patterns IP. The cover member CM may entirely cover the insulating patterns IP and may prevent a foreign substance, such as particles or portions of the insulating patterns IP, from being separated from the insulating patterns IP. The cover member CM may be filled in the separation space between the insulating patterns IP.

Each of the insulating patterns IP may include a first layer IP1 and a second layer IP2. The first layer IP1 may be disposed on the second insulating layer 20, and the second layer IP2 may be disposed on the first layer IP1. The first layer IP1 may be formed through the same process as the third insulating layer 30, and the second layer IP2 may be formed through the same process as the fourth insulating layer 40.

An inorganic layer area ILA may be defined between the first dam DM1 and the second dam DM2. The inorganic layer area ILA may be an area where only inorganic layers are stacked. The first inorganic layer IL1, the second inorganic layer IL2, the first sensing insulating layer IS-IL1, the second sensing insulating layer IS-IL2, and the third sensing insulating layer IS-IL3 may be sequentially stacked in the inorganic layer area ILA. As an example, in the inorganic layer area ILA, the second inorganic layer IL2 may be disposed on the first inorganic layer IL1 to be in contact with the first inorganic layer IL1, and the first sensing insulating layer IS-IL1 may be disposed on the second inorganic layer IL2 to be in contact with the second inorganic layer IL2. In addition, the second sensing insulating layer IS-IL2 may be disposed on the first sensing insulating layer IS-IL1 to be in contact with the first sensing insulating layer IS-IL1, and the third sensing insulating layer IS-IL3 may be disposed on the second sensing insulating layer IS-IL2 to be in contact with the second sensing insulating layer IS-IL2. For example, the second sensing insulating layer IS-IL2 may be in contact with the first sensing insulating layer IS-IL1 and the third sensing insulating layer IS-IL3 in the inorganic layer area ILA. A groove HM may be defined in the inorganic layer area ILA.

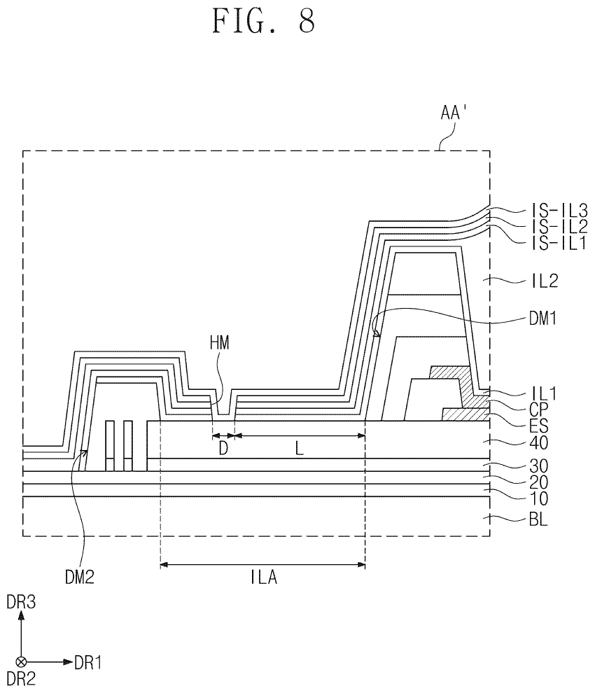

FIGS. 8 to 10 are enlarged views of the area AA′ in FIG. 7 according to various embodiments.

Referring to FIGS. 7 and 8, the groove HM may be defined in the inorganic layer area ILA. For example, the groove HM may overlap the non-display area NDA. The groove HM may be defined in the first inorganic layer IL1, the second inorganic layer IL2, the first sensing insulating layer IS-IL1, and the second sensing insulating layer IS-IL2. As an example, an inner side surface of the first inorganic layer IL1, an inner side surface of the second inorganic layer IL2, an inner side surface of the first sensing insulating layer IS-IL1, and an inner side surface of the second sensing insulating layer IS-IL2 may define the groove HM. The third sensing insulating layer IS-IL3 may be disposed on the second sensing insulating layer IS-IL2 and may cover the groove HM.

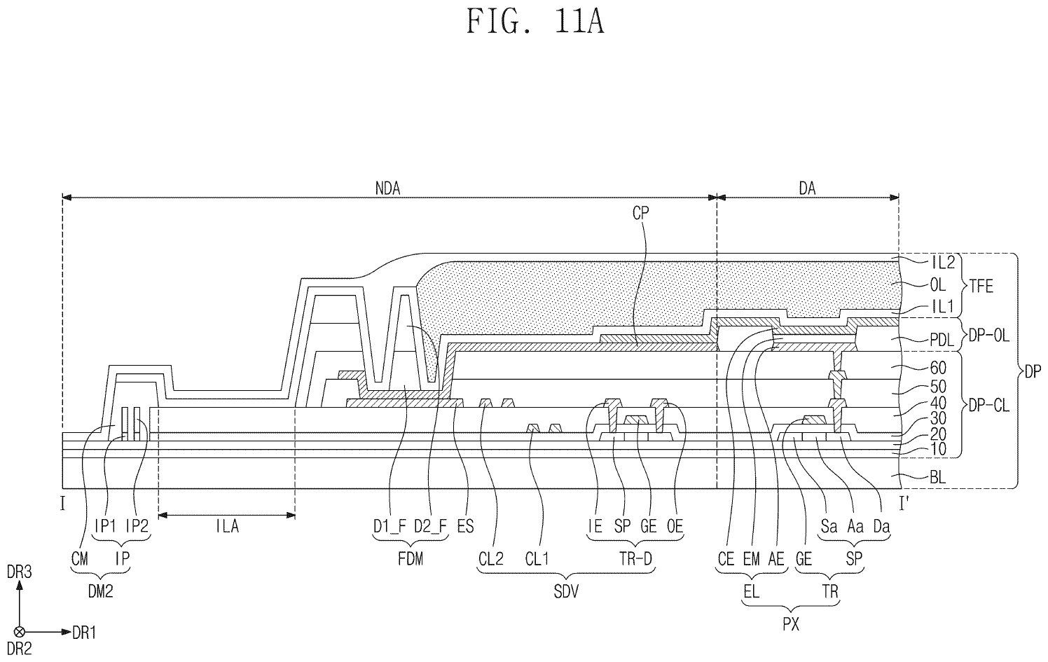

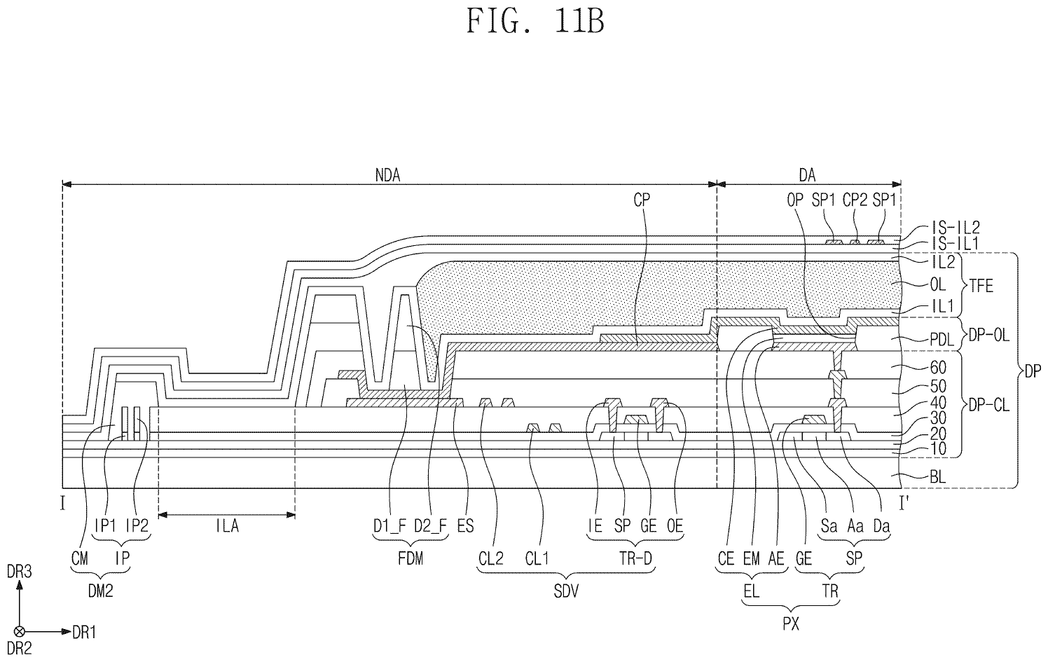

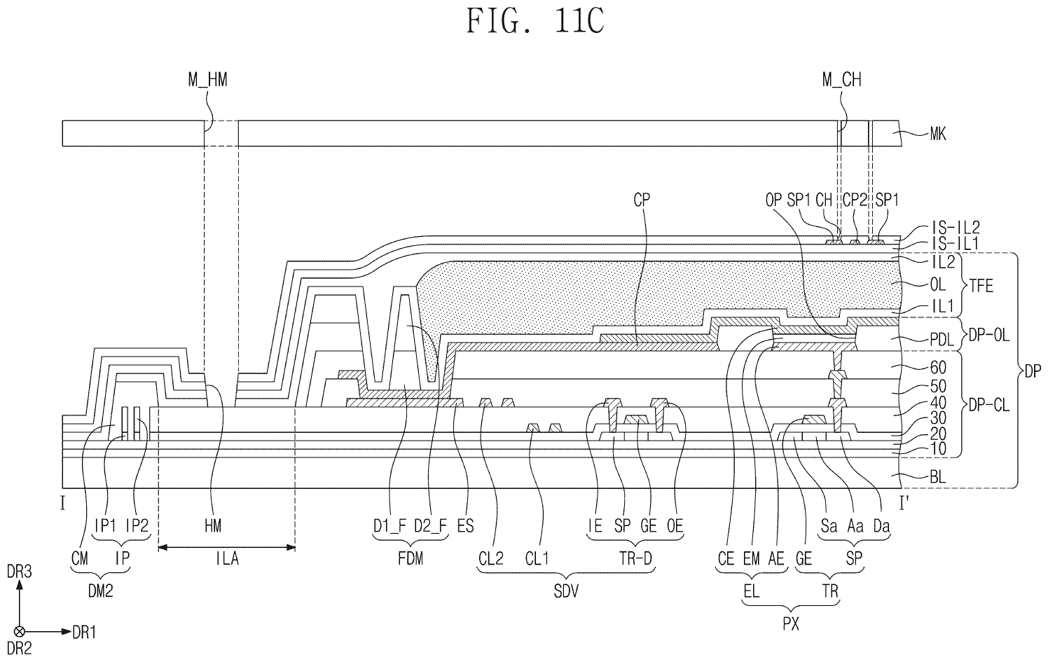

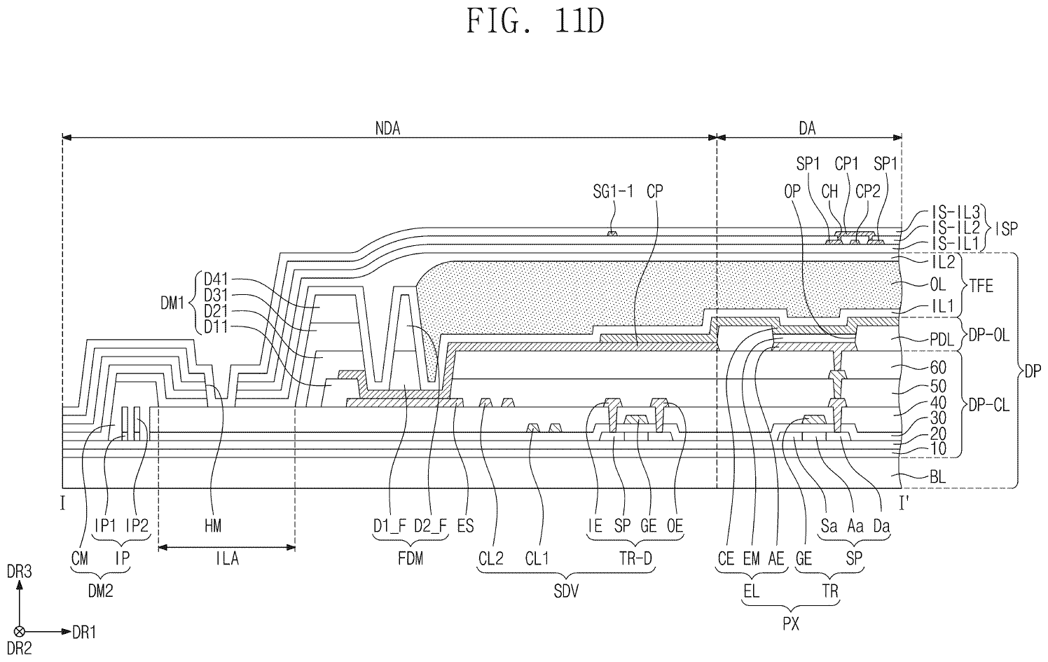

The contact hole CH at which a portion of the first conductive layer IS-CL1 (see, e.g., FIG. 4), for example, the first sensor portion SP1 (see, e.g., FIG. 6), and a portion of the second conductive layer IS-CL2 (see, e.g., FIG. 4), for example, the first connection portion CP1 (see, e.g., FIG. 6), are connected to each other is defined through the second sensing insulating layer IS-IL2, and the groove HM may be formed through the same process as the contact hole CH. As an example, the groove HM in the inorganic layer area ILA may be formed by using a mask MK (see, e.g., FIG. 11C) used to form the contact hole CH.

According to embodiments of the present disclosure, because the groove HM is formed in the inorganic layer area ILA, a foreign substance from the outside may be discharged upwardly through the groove HM. Accordingly, the foreign substance may be prevented from moving through the display area DA, and thus, defects of the display panel DP may be reduced or prevented.

The above descriptions on the groove HM of the inorganic layer area ILA may be applied to those of FIGS. 8 to 10. Hereinafter, descriptions will primarily focus on differences between grooves HM, HM-1, and HM-2 show in FIGS. 8 to 10, respectively.

Referring to FIG. 8, the groove HM may be defined closer to the second dam DM2 than to the first dam DM1. The groove HM may be spaced apart from the first dam DM1 by about 25 micrometers or more. That is, a separation distance L between the first dam DM1 and the groove HM may be equal to or greater than about 25 micrometers. A width D of the groove HM in the first direction DR1 may be equal to or greater than about 1 micrometer and equal to or smaller than about 10 micrometers.

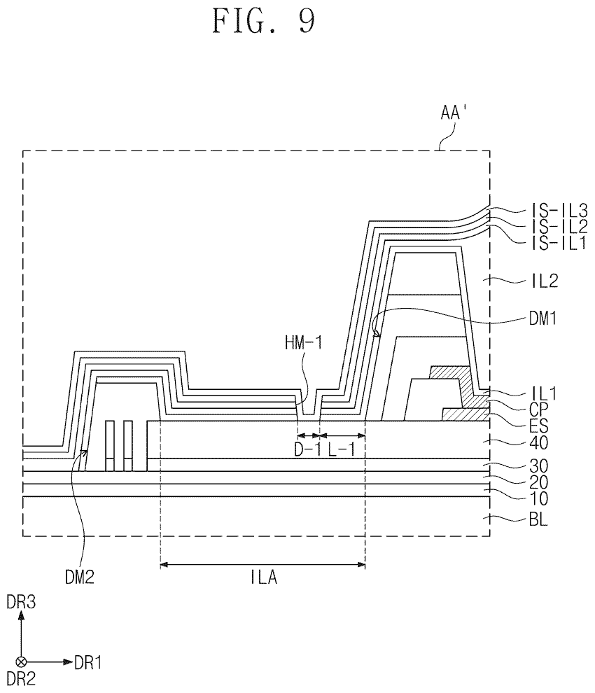

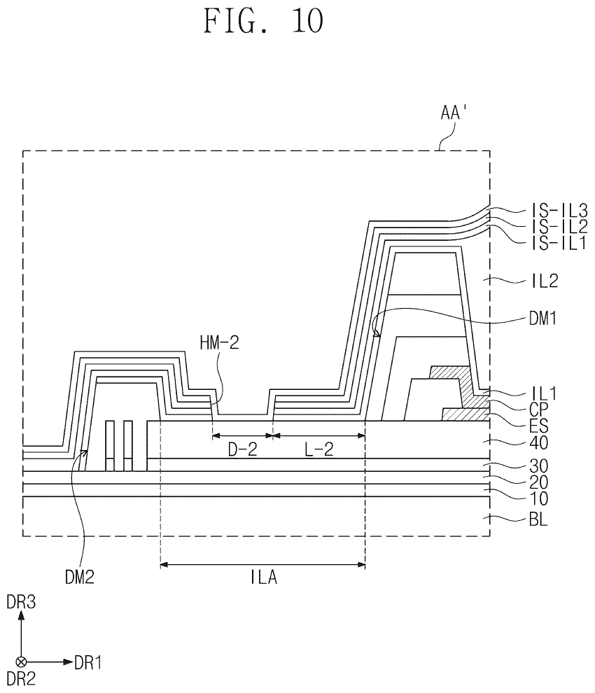

Referring to FIG. 9, the groove HM-1 may be defined closer to the first dam DM1 than to the second dam DM2. As an example, a separation distance L-1 between the groove HM-1 and the first dam DM1 in FIG. 9 may be smaller than a separation distance L between the groove HM and the first dam DM1 in FIG. 8. The separation distance L-1 between the first dam DM1 and the groove HM-1 may be equal to or greater than about 25 micrometers. That is, a position of the groove HM-1 defined in the inorganic layer area ILA is not limited as long as the separation distance L-1 between the first dam DM1 and the groove HM-1 is equal to or greater than about 25 micrometers. In addition, a width D-1 of the groove HM-1 in the first direction DR1 may be equal to or greater than about 1 micrometer and equal to or smaller than about 10 micrometers.

Referring to FIG. 10, the groove HM-2 may be defined closer to the second dam DM2 than to the first dam DM1. A separation distance L-2 between the first dam DM1 and the groove HM-2 may be equal to or greater than about 25 micrometers. A width D-2 of the groove HM-2 in the first direction DR1 may be greater than the width D of the groove HM in FIG. 8. For example, the width of the groove HM-2 defined in the inorganic layer area ILA is not limited as long as the width D-2 of the groove HM-2 in the first direction DR1 is equal to or smaller than about 10 micrometers.

FIGS. 11A to 11D are cross-sectional views illustrating steps of a method of manufacturing the display device according to an embodiment of the present disclosure. In FIGS. 11A to 11D, the same reference numerals denote the same elements in FIGS. 1 to 10, and thus, detailed descriptions of the same elements will be omitted.

A manufacturing method of the display device, according to an embodiment of the present disclosure, may include preparing a preliminary display panel including the base layer in which the display area and the non-display area adjacent to the display area are defined, the display element layer disposed on the base layer, and the encapsulation layer including the first inorganic layer, the organic layer, and the second inorganic layer, which are sequentially stacked on the display element layer, sequentially stacking the first sensing insulating layer, the first conductive layer, and the second sensing insulating layer on the preliminary display panel, forming a hole (e.g., an opening) through the first inorganic layer, the second inorganic layer, the first sensing insulating layer, and the second sensing insulating layer, which overlap the non-display area, and sequentially stacking the second conductive layer and the third sensing insulating layer on the second sensing insulating layer.

Referring to FIG. 11A, the manufacturing method of the display device may include preparing the display panel DP. The display panel DP may include the base layer BL, the circuit layer DP-CL, the display element layer DP-OL, and the encapsulation layer TFE.

The base layer BL may have (or may define) the display area DA and the non-display area NDA adjacent to the display area DA. The circuit layer DP-CL may be disposed on the base layer BL, and the display element layer DP-OL may be disposed on the circuit layer DP-CL. The display element layer DP-OL may include the pixels PX arranged to overlap the display area DA. The encapsulation layer TFE may include the first inorganic layer IL1, the organic layer OL, and the second inorganic layer IL2, which are sequentially stacked.

The display panel DP may further include the first dam DM1 and the second dam DM2, which are disposed in the non-display area NDA. The second dam DM2 may be spaced apart from the first dam DM1 in a direction away from the display area DA at the boundary between the display area DA and the non-display area NDA.

Referring to FIG. 11B, the manufacturing method of the display device may include sequentially stacking the first sensing insulating layer IS-IL1, the first conductive layer IS-CL1 (see, e.g., FIG. 4), and the second sensing insulating layer IS-IL2 on the display panel DP. As an example, the first sensing insulating layer IS-IL1 may be formed on the display panel DP, and the first conductive layer IS-CL1 may be formed on the first sensing insulating layer IS-IL1. FIG. 11B shows the second connection portion CP2 and the first sensor portions SP1, which are portions of the first conductive layer IS-CL1, as an example. The first conductive layer IS-CL1 may include the first sensor portions SP1, the second sensor portions SP2, and the second connection portions CP2. After the first conductive layer IS-CL1 is formed, the second sensing insulating layer IS-IL2 may be formed on the first conductive layer IS-CL1. The second sensing insulating layer IS-IL2 may cover the first sensor portions SP1, the second sensor portions SP2, and the second connection portions CP2.

Referring to FIG. 11C, the manufacturing method of the display device may include forming the groove HM in the first inorganic layer IL1, the second inorganic layer IL2, the first sensing insulating layer IS-IL1, and the second sensing insulating layer IS-IL2. The groove HM may be formed in the inorganic layer area ILA defined in the non-display area NDA. That is, the groove HM may overlap the non-display area NDA.

The forming of the groove HM may include forming the contact hole CH at which a portion of the first conductive layer IS-CL1 (see, e.g., FIG. 4), for example, the first sensor portion SP1, and a portion of the second conductive layer IS-CL2 (see, e.g., FIG. 4), for example, the first connection portion CP1, are connected to each other. The process of forming the groove HM may be substantially the same as the process of forming the contact hole CH. As an example, the groove HM may be formed in the second sensing insulating layer IS-IL2 by using the same mask MK as the mask MK used to form the contact hole CH.

For example, the mask MK may be aligned above the display panel DP. The mask MK may have a plurality of mask openings M_HM and M_CH defined therethrough. The mask openings M_HM and M_CH may include a groove mask opening M_HM and a contact hole mask opening M_CH. The groove mask opening M_HM may be defined to correspond to the area where the groove HM is to be formed, and the contact hole mask opening M_CH may be defined to correspond to the area where the contact hole CH is to be formed. After the mask MK is disposed, at least portions of the first inorganic layer IL1, the second inorganic layer IL2, the first sensing insulating layer IS-IL1, and the second sensing insulating layer IS-IL2 may be removed through an exposure process, and thus, the groove HM and the contact hole CH may be formed.

The forming of the groove HM may include etching the first inorganic layer IL1, the second inorganic layer IL2, the first sensing insulating layer IS-IL1, and the second sensing insulating layer IS-IL2 in the area spaced apart from the first dam DM1 by about 25 micrometers or more. In addition, the groove HM formed by etching the first inorganic layer IL1, the second inorganic layer IL2, the first sensing insulating layer IS-IL1, and the second sensing insulating layer IS-IL2 may have the width equal to or smaller than about 10 micrometers.

According to embodiments of the present disclosure, when the groove HM is formed in the inorganic layer area ILA, a foreign substance from the outside may be discharged upwardly through the groove HM. Accordingly, the foreign substance may be prevented from moving into or through the display area DA, and thus, defects of the display panel DP may be reduced or prevented. In addition, because the groove HM is formed by using the same mask MK as the mask used to form the contact hole CH of the input sensor ISP, the manufacturing method of the display panel may be simplified.

Referring to FIG. 11D, the manufacturing method of the display device may include sequentially stacking the second conductive layer IS-CL2 and the third sensing insulating layer IS-IL3 on the second sensing insulating layer IS-IL2. As an example, the second conductive layer IS-CL2 may be formed on the second sensing insulating layer IS-IL2, and the third sensing insulating layer IS-IL3 may be formed on the second conductive layer IS-CL2. FIG. 11D shows the first connection portion CP1 that is the portion of the second conductive layer IS-CL2 as an example. The third sensing insulating layer IS-IL3 may be formed to cover the groove HM in the inorganic layer area ILA.

Although embodiments of the present disclosure have been described, it is understood that the present disclosure should not be limited to these embodiments but various changes and modifications can be made by one ordinary skilled in the art within the spirit and scope of the present disclosure as defined by the appended claimed and their equivalents. Therefore, the disclosed subject matter should not be limited to any single embodiment described herein, and the scope of the present disclosure shall be determined according to the attached claims and their equivalents.

What is claimed is:

1. A display device comprising:
a base layer having a display area and a non-display area adjacent to the display area;
a display element layer comprising a plurality of light emitting elements overlapping the display area;
an encapsulation layer on the display element layer;
a first dam in the non-display area; and
a second dam in the non-display area and spaced apart from the first dam in a direction away from the display area from a boundary between the display area and the non-display area,
wherein an inorganic layer area is defined between the first dam and the second dam, and
wherein a groove is defined in the inorganic layer area.

2. The display device of claim 1, wherein the encapsulation layer comprises a first inorganic layer, an organic layer, and a second inorganic layer, which are sequentially arranged on the display element layer, and
wherein the second inorganic layer is in contact with the first inorganic layer in the inorganic layer area.

3. The display device of claim 2, further comprising a sensor layer comprising a first sensing insulating layer, a first conductive layer, a second sensing insulating layer, a second conductive layer, and a third sensing insulating layer, which are sequentially arranged on the encapsulation layer, and
wherein the second sensing insulating layer is in contact with the first sensing insulating layer and the third sensing insulating layer in the inorganic layer area.

4. The display device of claim 3, wherein the groove is defined in the first inorganic layer, the second inorganic layer, the first sensing insulating layer, and the second sensing insulating layer.

5. The display device of claim 3, wherein the groove is defined closer to the second dam than to the first dam when viewed in a plane.

6. The display device of claim 3, wherein the third sensing insulating layer is on the second sensing insulating layer and covers the groove.

7. The display device of claim 3, wherein a contact hole at where the first conductive layer and the second conductive layer are connected to each other extends through the second sensing insulating layer, and
wherein the groove is formed through a same process as the contact hole.

8. The display device of claim 1, wherein the groove is spaced apart from the first dam by 25 micrometers or more.

9. The display device of claim 1, wherein the groove has a width equal to or smaller than 10 micrometers in a first direction.

10. A display device comprising:
a base layer having a display area and a non-display area adjacent to the display area;
a display element layer comprising a plurality of light emitting elements overlapping the display area;
an encapsulation layer comprising a first inorganic layer, an organic layer, and a second inorganic layer, which are sequentially arranged on the display element layer; and
a sensor layer comprising a first sensing insulating layer, a first conductive layer, a second sensing insulating layer, a second conductive layer, and a third sensing insulating layer, which are sequentially arranged on the encapsulation layer,
wherein a groove is defined in the first inorganic layer, the second inorganic layer, the first sensing insulating layer, and the second sensing insulating layer, and
wherein the groove overlaps the non-display area.

11. The display device of claim 10, further comprising:
a first dam in the non-display area; and
a second dam in the non-display area and spaced apart from the first dam in a direction away from the display area from a boundary between the display area and the non-display area,
wherein an inorganic layer area is defined between the first dam and the second dam, and
wherein the groove is defined in the inorganic layer area.

12. The display device of claim 11, wherein the first inorganic layer, the second inorganic layer, the first sensing insulating layer, the second sensing insulating layer, and the third sensing insulating layer are sequentially stacked in the inorganic layer area.

13. The display device of claim 11, wherein the groove is spaced apart from the first dam by 25 micrometers or more.

14. The display device of claim 10, wherein a contact hole at where the first conductive layer and the second conductive layer are connected to each other is defined through the second sensing insulating layer, and
wherein the groove is formed through a same process as the contact hole.

15. The display device of claim 10, wherein the third sensing insulating layer is on the second sensing insulating layer and covers the groove.

16. The display device of claim 10, wherein the groove has a width equal to or smaller than 10 micrometers in a first direction.

17. A method of manufacturing a display device, the method comprising:
preparing a display panel comprising a base layer in which a display area and a non-display area adjacent to the display area are defined, a circuit layer on the base layer, a display element layer on the circuit layer, and an encapsulation layer comprising a first inorganic layer, an organic layer, and a second inorganic layer, which are sequentially stacked on the display element layer;
sequentially stacking a first sensing insulating layer, a first conductive layer, and a second sensing insulating layer on the display panel;
forming a hole through the first inorganic layer, the second inorganic layer, the first sensing insulating layer, and the second sensing insulating layer, which overlap the non-display area; and
sequentially stacking a second conductive layer and a third sensing insulating layer on the second sensing insulating layer.

18. The method of claim 17, wherein the forming of the hole comprises forming a contact hole at where the first conductive layer and the second conductive layer are connected to each other.

19. The method of claim 17, wherein the display panel further comprises a first dam in the non-display area and a second dam spaced apart from the first dam in a direction away from the display area from a boundary between the display area and the non-display area,
wherein the forming of the hole comprises etching the first inorganic layer, the second inorganic layer, the first sensing insulating layer, and the second sensing insulating layer in an area spaced apart from the first dam by 25 micrometers or more.

20. The method of claim 17, wherein the forming of the hole comprises etching the first inorganic layer, the second inorganic layer, the first sensing insulating layer, and the second sensing insulating layer such that the hole has a width equal to or smaller than 10 micrometers.
